(19) United States
(12) Patent Application Publication
(10) Pub. No.: US 2026/0156766 A1
(43) Pub. Date: Jun. 4, 2026

(54) WINDOW, METHOD OF MANUFACTURING WINDOW, AND ELECTRONIC DEVICE

(71) Applicant: SAMSUNG DISPLAY CO., LTD., YONGIN-SI (KR)

(72) Inventors: Jiwon Min, Yongin-si (KR); SEUNG KIM, Yongin-si (KR); SEUNGHO KIM, Yongin-si (KR); HYUNSEUNG SEO, Yongin-si (KR); SEONGJIN HWANG, Yongin-si (KR)

(21) Appl. No.: 19/333,659

(22) Filed: Sep. 19, 2025

(30) Foreign Application Priority Data
Dec. 3, 2024 (KR) 10-2024-0177036

(51) Int. Cl. H05K 5/03; G02B 1/14

(52) U.S. Cl. CPC H05K 5/03; G02B 1/14

(57) ABSTRACT

A window includes a glass product and an anti-reflection layer arranged on a first surface of the glass product. The glass product includes the first surface, a second surface facing the first surface in a thickness direction and having a compression stress that is less than a compression stress of the first surface. A base substrate defines the second surface. A stress compensation layer is arranged on the base substrate. The stress compensation layer defines the first surface, and includes a different material from a material of the base substrate.

### CROSS-REFERENCE TO RELATED APPLICATION(S)

This application claims priority under 35 USC § 119 to Korean Patent Application No. 10-2024-0177036, filed on Dec. 3, 2024 in the Korean Intellectual Property Office, the disclosure of which is incorporated by reference in its entirety herein.

### 1. Technical Field

Embodiments relate to a window. More specifically, embodiments relate to a window, a method of manufacturing the window, and an electronic device including the window.

### 2. Discussion of Related Art

Glass products are used in various electronic devices including display devices, building materials, or the like. For example, the glass products may be applied to substrates of the display devices, windows that protect display panels of the display devices, or the like.

The glass products applied to display devices are preferably thin for compactness and portability and have good strength to withstand external impacts. The strength of the glass products may be increased to withstand external impacts through thermal strengthening or chemical strengthening.

### SUMMARY

Embodiments provide a window with increased bending properties.

Embodiments provide a method of manufacturing the window.

Embodiments provide an electronic device including the window.

According to an embodiment of the present disclosure, a window includes a glass product including a first surface, a second surface facing the first surface in a thickness direction of the glass product. The second surface has a compression stress that is less than a compression stress of the first surface. A base substrate defines the second surface. A stress compensation layer is arranged on the base substrate. The stress compensation layer defines the first surface, and includes a material different from a material of the base substrate. An anti-reflection layer is arranged on the first surface of the glass product.

In an embodiment, the glass product may have a stress that bends the window in a first direction, and the anti-reflection layer may have a stress that bends the window in a second direction opposite to the first direction.

In an embodiment, the stress of the glass product may be substantially equal to the stress of the anti-reflection layer.

In an embodiment, the stress compensation layer may include tin ions.

In an embodiment, the anti-reflection layer may include a first layer and a second layer arranged on the first layer. The second layer has a hardness greater than a hardness of the first layer.

In an embodiment, a thickness of the first layer may be less than a thickness of the second layer.

In an embodiment, a proportion of a volume of the first layer in a total volume of the anti-reflection layer may be less than a proportion of a volume of the second layer in the total volume of the anti-reflection layer.

In an embodiment, the first layer and the second layer may be alternately arranged along a thickness direction of the anti-reflection layer.

In an embodiment, the glass product may include a first compression area extending from the first surface to a first depth and a second compression area extending from the second surface to a second depth, and the first depth may be less than the second depth.

In an embodiment, the glass product may be manufactured by a float process.

According to an embodiment of the present disclosure, a method of manufacturing a window includes forming a glass product including a first surface, a second surface facing the first surface in a thickness direction of the glass product. The second surface having a compression stress that is less than a compression stress of the first surface. A base substrate defines the second surface. A stress compensation layer is arranged on the base substrate. The stress compensation layer defines the first surface, and includes a material different from a material of the base substrate. An anti-reflection layer is formed on the first surface of the glass product.

In an embodiment, the glass product may have a stress that bends the window in a first direction, and in the forming of the glass product, the glass product may be bent in the first direction by the stress of the glass product.

In an embodiment, the anti-reflection layer may have a stress that bends the window in a second direction opposite to the first direction, and in the forming of the anti-reflection layer, the glass product and the anti-reflection layer may be bent in the second direction opposite to the first direction by the stress of the anti-reflection layer.

In an embodiment, the stress of the glass product may be substantially equal to the stress of the anti-reflection layer.

In an embodiment, the glass product may be manufactured by a float process, and the stress compensation layer may include tin ions.

In an embodiment, the anti-reflection layer may include a first layer and a second layer arranged on the first layer and having a hardness greater than a hardness of the first layer.

In an embodiment, a thickness of the first layer may be less than a thickness of the second layer.

In an embodiment, a proportion of a volume of the first layer in a total volume of the anti-reflection layer may be less than a proportion of a volume of the second layer in the total volume of anti-reflection layer.

In an embodiment, the first layer and the second layer may be alternately arranged along a thickness direction of the anti-reflection layer.

According to an embodiment of the present disclosure, an electronic device includes a display device and a processor that controls the display device. The display device includes a display panel including a plurality of pixels arranged in a display area and a window arranged on the display panel. The window includes a glass product including a first surface, a second surface facing the first surface in a thickness direction of the glass product. The second surface having a compression stress that is less than a compression stress of the first surface. A base substrate defines the second surface. A stress compensation layer is arranged on the base substrate. The stress compensation layer defines the first surface, and including a material different from a material of the base substrate. An anti-reflection layer is arranged on the first surface of the glass product.

In a window according to embodiments of the present disclosure, the window may include a glass product manufactured by a float process and including a stress compensation layer (e.g., a tin surface) and an anti-reflection layer arranged on the stress compensation layer. A stress of the anti-reflection layer that causes bending of the window in one direction may be compensated for by a stress of the glass product including the stress compensation layer that causes bending of the window in a direction opposite to the one direction. Accordingly, bending of the window may be effectively reduced.

### BRIEF DESCRIPTION OF THE DRAWINGS

FIG. 1 is a perspective view illustrating a display device according to an embodiment of the present disclosure.

FIG. 2 is an exploded perspective view illustrating the display device of FIG. 1 according to an embodiment of the present disclosure.

FIG. 3 is a cross-sectional view illustrating a window of the display device of FIG. 1 according to an embodiment of the present disclosure.

FIG. 4 is a cross-sectional view illustrating a glass product of the window of FIG. 3 according to an embodiment of the present disclosure.

FIG. 5 is a schematic diagram illustrating ion exchange for chemical strengthening according to an embodiment of the present disclosure.

FIG. 6 is a cross-sectional view illustrating an anti-reflection layer of the window of FIG. 3 according to an embodiment of the present disclosure.

FIG. 7 is a cross-sectional view illustrating a display panel of the display device of FIG. 1 according to an embodiment of the present disclosure.

FIGS. 8, 9, 10, 11, 12, 13, and 14 are views illustrating a method of manufacturing a window according to embodiments of the present disclosure.

FIG. 15 is a graph comparing flatness of windows of comparative example and an embodiment.

FIG. 16 is a block diagram illustrating an electronic device according to an embodiment of the present disclosure.

FIG. 17 is a diagram illustrating an example in which the electronic device of FIG. 16 is implemented as a smartphone according to an embodiment of the present disclosure.

### DETAILED DESCRIPTION OF EMBODIMENTS

Hereinafter, embodiments of the present disclosure will be described in more detail with reference to the accompanying drawings. The same reference numerals are used for the same components in the drawings, and redundant descriptions of the same components will be omitted.

The present disclosure concerns a window that includes a glass product having a stress compensation layer arranged on a base substrate. An anti-reflection layer is arranged on the stress compensation layer. The anti-reflection layer may cause the window to bend in a first direction due to tensile stress of the anti-reflection layer.

The stress compensation layer includes a tin layer on a first surface contacting the anti-reflection layer. The tin layer may be formed by manufacturing the glass product through a float process in which the first surface directly contacts molten tin. The stress compensation layer may cause bending of the window in a second direction opposite to the first direction. Therefore, the window may have reduced bending.

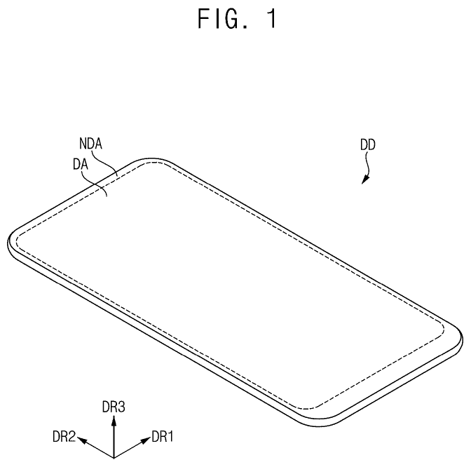

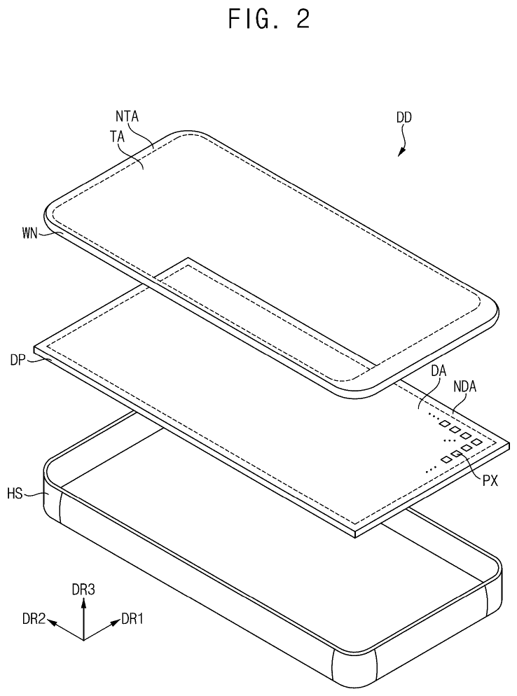

FIG. 1 is a perspective view illustrating a display device according to an embodiment of the present disclosure. FIG. 2 is an exploded perspective view illustrating the display device of FIG. 1.

Referring to FIGS. 1 and 2, a display device DD may include a display panel DP, a window WN, and a housing member HS.

The display panel DP may include a display area DA and a non-display area NDA. The display area DA and the non-display area NDA of the display panel DP may correspond to a display area and a non-display area of the display device DD, respectively.

The display area DA may be an area that generates light to display at least one moving and/or still image. A plurality of pixels PX for displaying an image may be arranged in the display area DA. The pixels PX may be arranged along a first direction DR1 and a second direction DR2 intersecting the first direction DR1. For example, in an embodiment the second direction DR2 may be perpendicular to the first direction DR1. Each of the pixels PX may emit light, and accordingly, at least one moving and/or still image may be displayed in the display area DA. For example, the image may be displayed in a third direction DR3 intersecting each of the first and second directions DR1 and DR2 in the display area DA. For example, the third direction DR3 may be perpendicular to each of the first and second directions DR1 and DR2. However, embodiments of the present disclosure are not necessarily limited thereto and the first to third directions DR1, DR2, DR3 may intersect each other at various different angles. Each of the pixels PX may include a light emitting element and a pixel circuit for driving the light emitting element.

The non-display area NDA may be an area that does not display an image. The non-display area NDA may be adjacent to the display area DA (e.g., in the first and/or second directions DR1, DR2). For example, the non-display area NDA may surround the display area DA in a plan view. In an embodiment, a driving circuit, a driving line, or the like for driving the display area DA may be arranged in the non-display area NDA.

The window WN may be arranged on the display panel DP. For example, the window WN may be adjacent to the display panel DP in the third direction DR3. The window WN may cover an upper surface of the display panel DP. The window WN may protect the display panel DP from external impact. In an embodiment, the window WN may include glass, plastic, or the like. The window WN may define a front surface of the display device DD. The window WN may include a transmissive area TA and a non-transmissive area NTA.

The transmissive area TA may be an area that transmits incident light. The transmissive area TA may be an optically transparent area. For example, in an embodiment the transmissive area TA may be an area having a visible light transmittance in a range greater than or equal to about 90%.

The transmissive area TA may overlap at least a portion of the display area DA in a plan view. For example, in an embodiment the transmissive area TA may entirely overlap the display area DA in a plan view. The transmissive area TA may have a shape corresponding to the display area DA. The image displayed on the display area DA of the display panel DP may transmit through the transmissive area TA to be visually recognized from outside (e.g., the external environment). For example, the display device DD may display the image in the third direction DR3 through the display area DA and the transmissive area TA.

The non-transmissive area NTA may be an area that does not transmit light. The non-transmissive area NTA may be an area having a relatively lower light transmittance than the transmissive area TA. The non-transmissive area NTA may be adjacent to the transmissive area TA (e.g., in the first and/or second directions DR1, DR2). For example, the non-transmissive area NTA may surround the transmissive area TA in a plan view. The non-transmissive area NTA may define a shape of the transmissive area TA. For example, the non-transmissive area NTA may have a selected color. For example, the window WN may further include a printed layer arranged in the non-transmissive area NTA (e.g., an edge of the window WN).

The non-transmissive area NTA may overlap at least a portion of the non-display area NDA. For example, in an embodiment the non-transmissive area NTA may entirely overlap the non-display area NDA in a plan view. The non-transmissive area NTA may cover the non-display area NDA to block the non-display area NDA from being visually recognized from the outside (e.g., the external environment).

The housing member HS may be arranged below the display panel DP. The housing member HS may be coupled to the window WN to form an exterior of the display device DD. The housing member HS may be coupled to the window WN to provide an accommodation space. The display panel DP may be accommodated in the accommodation space provided between the housing member HS and the window WN. The housing member HS may protect the display panel DP from external impact by accommodating the display panel DP in the accommodation space. In an embodiment, the housing member HS may include a plurality of frames and/or plates. The housing member HS may include a material having relatively high rigidity. For example, the housing member HS may include glass, plastic, metal, or the like.

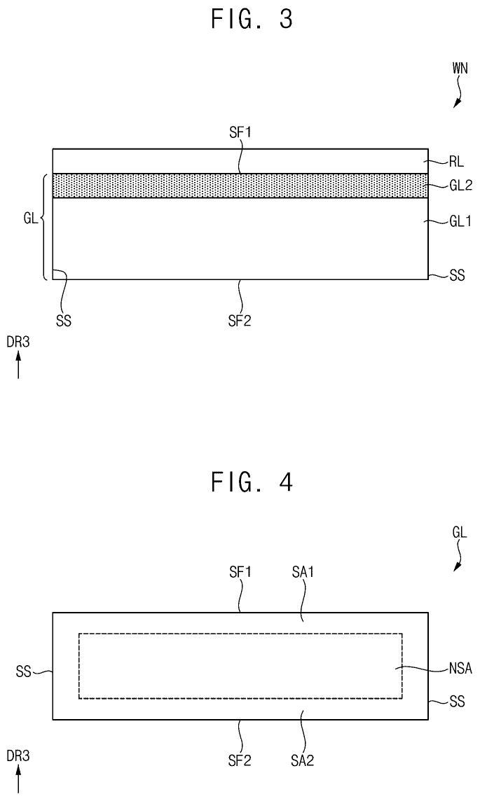

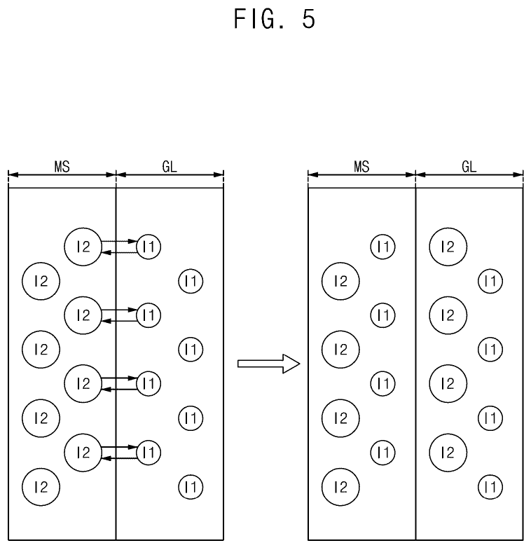

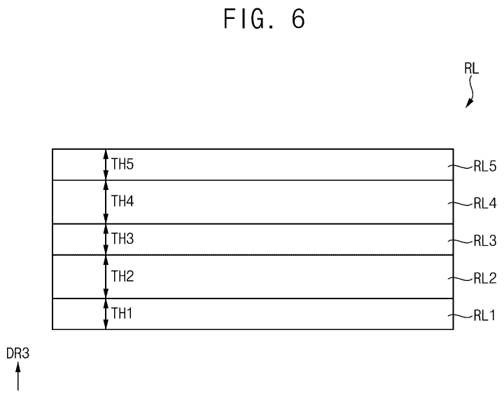

FIG. 3 is a cross-sectional view illustrating a window of the display device of FIG. 1. FIG. 4 is a cross-sectional view illustrating a glass product of the window of FIG. 3. FIG. 5 is a schematic diagram illustrating ion exchange for chemical strengthening. FIG. 6 is a cross-sectional view illustrating an anti-reflection layer of the window of FIG. 3.

Referring to FIGS. 2, 3, 4, 5, and 6, the window WN may include a glass product GL (e.g., a glass) and an anti-reflection layer RL. In an embodiment, the glass product GL may include a base substrate GL1 and a stress compensation layer GL2.

The stress compensation layer GL2 may be arranged on the base substrate GL1. For example, the stress compensation layer GL2 may be adjacent to (e.g., disposed directly thereon) the base substrate GL1 in the third direction DR3. The stress compensation layer GL2 may include a material different from a material of the base substrate GL1.

The glass product GL may include a first surface SF1, a second surface SF2 facing the first surface SF1 in a thickness direction of the glass product GL (e.g., opposite to each other in the third direction DR3), and a side surface SS connecting the first surface SF1 and the second surface SF2 to each other. For example, in an embodiment each of the first surface SF1 and the second surface SF2 may extend in a plane defined in the first direction DR1 and the second direction DR2. The first surface SF1 and the second surface SF2 may be main surfaces of the glass product GL. The stress compensation layer GL2 may define the first surface SF1, and the base substrate GL1 may define the second surface SF2. For example, in an embodiment, the first surface SF1 may be an uppermost surface of the glass product GL (e.g., in the third direction DR3) and the second surface SF2 may be a lowermost surface of the glass product GL (e.g., in a direction opposite to the third direction DR3).

In an embodiment, the glass product GL may include a first compression area SA1 extending (or expanding) from the first surface SF1 to a compression depth (e.g., a first depth), a second compression area SA2 extending (or expanding) from the second surface SF2 and the side surface SS to a compression depth (e.g., a second depth), and a non-compression area NSA surrounded by the first and second compression areas SA1 and SA2 (e.g., completely surrounded in a cross-sectional view) and located inside the glass product GL.

In an embodiment, the glass product GL may be manufactured through a float process. In a process of manufacturing the glass product GL through the float process, the first surface SF1 may be manufactured by directly contacting molten tin, and the second surface SF2 and the side surface SS may be manufactured without directly contacting molten tin. Accordingly, in a chemical strengthening process during the process of manufacturing the glass product GL, ion exchange of a different aspect from that of the second surface SF2 and the side surface SS may be performed on the first surface SF1, and ion exchange of a similar aspect may be performed on the second surface SF2 and the side surface SS.

The first compression area SA1 and the second compression area SA2 may be areas that serve to protect the glass product GL from external impact. A strength of the glass product GL may increase as a maximum compression stress of the first and second compression areas SA1 and SA2 increases. The compression stress of the first and second compression areas SA1 and SA2 may be greatest at outermost surfaces of the glass product GL (e.g., the first and second surfaces SF1 and SF2 and the side surface SS), and may relatively decrease towards an inside of the glass product GL. The first compression area SA1 may have a first compression depth, and the second compression area SA2 may have a second compression depth. The first and second compression depths may be defined as boundaries between the first and second compression areas SA1 and SA2 and the non-compression area NSA, respectively. The first compression depth and the second compression depth may prevent cracks, defects, or the like formed on the first and second surfaces SF1 and SF2 and the side surface SS from being transmitted to the non-compression area NSA inside the glass product GL to increase the strength and structural stability of the window WN.

The first compression area SA1 and the second compression area SA2 may be formed through chemical strengthening by ion exchange. Referring to FIG. 5, in an embodiment in which the glass product GL including a first ion I1 is exposed to a second ion I2 included in a molten salt MS by a method such as immersing the glass product GL in a bath including the molten salt MS, the first ion I1 included in the glass product GL and the second ion I2 included in the molten salt MS may be exchanged.

In an embodiment, the first ion I1 and the second ion I2 may have the same valence or oxidation state as each other. In addition, an ion radius of the second ion I2 may be greater than an ion radius of the first ion I1. For example, in an embodiment the first ion I1 may include Li⁺, Na⁺, K⁺, Rb⁺, or the like, and the second ion I2 may include Na⁺, K⁺, Rb⁺, Cs⁺, or the like. For example, in an embodiment in which the first ion I1 is Na⁺and the second ion I2 is K⁺, Na⁺ included in the glass product GL may be exchanged with K⁺included in the molten salt MS.

Since the ion radius of the second ion I2 may be greater than the ion radius of the first ion I1, when the first ion I1 included in the glass product GL is exchanged with the second ion I2, compression stress may occur in the glass product GL. As an amount of the second ion I2 exchanged with the first ion I1 increases, the compression stress may increase.

Since the exchange of the first ion I1 and the second ion I2 occurs through the surfaces SF1, SF2, and SS and a vicinity of the surfaces SF1, SF2, and SS of the glass product GL, an amount of the second ion I2 may be the greatest at the surfaces SF1, SF2, and SS of the glass product GL. A portion of the exchanged second ion I2 may diffuse into the inside of the glass product GL to increase the compression depth of the compression areas SA1 and SA2, but the amount of the diffused second ion I2 may generally decrease as a distance from the outermost surfaces, such as surfaces SF1, SF2, and SS increases. Therefore, the compression stress may be the greatest at the surfaces SF1, SF2, and SS of the glass product GL, and the compression stress may decrease towards the inside of the glass product GL. However, embodiments of the present disclosure are not necessarily limited thereto, and the compression stress may be modified according to temperature, time, number of times, heat treatment, or the like of the ion exchange process.

When properties of the surfaces SF1, SF2, and SS of the glass product GL are different, the ion exchange described above may be performed in different aspects on the surfaces SF1, SF2, and SS. For example, the glass product GL manufactured by the float process may have different tin component amounts on the first surface SF1 and the second surface SF2, and when ion exchange is performed, compression stress of the first compression area SA1 and compression stress of the second compression area SA2 may be different from each other.

In an embodiment, the glass product GL may be manufactured through a float process, and the float process may be performed on molten tin. A portion of tin ions of the molten tin may penetrate into the glass product GL through the first surface SF1 to form a tin layer in the first compression area SA1. Here, the first surface SF1 on which the tin layer is formed may be referred to as a tin surface, and the second surface SF2 on which the tin layer is not formed may be referred to as a non-tin surface. In addition, the tin layer may be referred to as the stress compensation layer GL2.

Due to a large coefficient of thermal expansion of tin, at a temperature at which chemical strengthening occurs, ion exchange with the outside (e.g., the molten tin accommodated in a bath, etc.) may be actively performed on the first surface SF1, which is a tin surface, compared to the second surface SF2, which is a non-tin surface. Therefore, a greater amount of the second ions I2 may be introduced into the first surface SF1. In addition, tin ions may inhibit diffusion of the second ions I2. Therefore, a greater amount of the second ions I2 may be distributed in a narrower thickness area on the first surface SF1 than the second surface SF2. For example, inside the glass product GL, an area near the first surface SF1 of the first compression area SA1 may have a greater density of the second ions I2 than an area near the second surface SF2 of the second compression area SA2.

Accordingly, a maximum compression stress of the first compression area SA1 may be relatively greater than a maximum compression stress of the second compression area SA2, and the first compression depth of the first compression area SA1 may be relatively less than the second compression depth of the second compression area SA2. Due to a deviation of the compressive stresses of the first surface SF1 and the second surface SF2 which face each other, the glass product GL may be bent (e.g., warped). For example, in an embodiment the glass product GL may be convexly bent in a direction towards the base substrate GL1 (e.g., a direction opposite to the third direction DR3). For example, an edge of the glass product GL may be bent towards the first surface SF1. For example, when the window WN includes the glass product GL, the window WN may be convexly bent in a direction towards the base substrate GL1 with an edge bent towards the first surface SF1.

After the chemical strengthening process is performed, a coating process may be performed to form the anti-reflection layer RL on the glass product GL. In an embodiment, the anti-reflection layer RL may be arranged on (e.g., disposed directly thereon in the third direction DR3) the first surface SF1 (e.g., the stress compensation layer GL2). For example, the anti-reflection layer RL may be adjacent to the glass product GL in the third direction DR3. For example, in an embodiment the base substrate GL1, the stress compensation layer GL2, and the anti-reflection layer RL may be arranged (e.g., consecutively disposed) along the third direction DR3. The anti-reflection layer RL may reduce reflectance of external light.

In an embodiment, the anti-reflection layer RL may have a structure in which a plurality of layers are stacked (e.g., in the third direction DR3). For example, in an embodiment the anti-reflection layer RL may include a first layer RL1, a second layer RL2, a third layer RL3, a fourth layer RL4, and a fifth layer RL5. The first, second, third, fourth, and fifth layers RL1, RL2, RL3, RL4, and RL5 may be sequentially arranged along the third direction DR3.

In an embodiment, the first, third, and fifth layers RL1, RL3, and RL5 may be layers having a relatively low refractive index, and the second and fourth layers RL2 and RL4 may be layers having relatively high refractive index. For example, each of the first, third, and fifth layers RL1, RL3, and RL5 may be referred to as a low refractive layer, and each of the second and fourth layers RL2 and RL4 may be referred to as a high refractive layer. The anti-reflection layer RL may have a structure in which a low refractive layer and a high refractive layer are alternately stacked along a thickness direction of the anti-reflection layer RL (e.g., along the third direction DR3).

In an embodiment, the first, second, third, fourth, and fifth layers RL1, RL2, RL3, RL4, and RL5 may include an inorganic material such as silicon oxide, silicon nitride, or the like. For example, the first layer RL1 may include silicon oxynitride (SiOₓN_{y}), the second layer RL2 may include aluminum silicon nitride (AlSiNₓ), the third layer RL3 may include silicon oxide (SiOₓ), the fourth layer RL4 may include aluminum silicon nitride (AlSiNₓ), and the fifth layer RL5 may include silicon oxide (SiOₓ), but embodiments of the present disclosure are not necessarily limited thereto. The refractive index of each of the first, second, third, fourth, and fifth layers RL1, RL2, RL3, RL4, and RL5 may be controlled by changing a content of a material included in each of the first, second, third, fourth, and fifth layers RL1, RL2, RL3, RL4, and RL5.

In an embodiment, a hardness of the first, third, and fifth layers RL1, RL3, and RL5 may be relatively less than a hardness of the second and fourth layers RL2 and RL4. For example, each of the first, third, and fifth layers RL1, RL3, and RL5 may be referred to as a low hardness layer, and each of the second and fourth layers RL2 and RL4 may be referred to as a high hardness layer. The anti-reflection layer RL may have a structure in which a low hardness layer and a high hardness layer are alternately stacked along the thickness direction of the anti-reflection layer RL (e.g., along the third direction DR3).

The first, second, third, fourth, and fifth layers RL1, RL2, RL3, RL4, and RL5 may have different thicknesses from each other. Here, the thickness may be a length in the third direction DR3, which is a thickness direction.

In an embodiment, a thickness of each of the first, third and fifth layers RL1, RL3, and RL5 may be relatively less than a thickness of each of the second and fourth layers RL2 and RL4. For example, a thickness of the high hardness layer may be relatively greater than a thickness of the low hardness layer. In an embodiment, a proportion (e.g., total volume) of the first, third, and fifth layers RL1, RL3, and RL5 in the anti-reflection layer RL may be relatively less than a proportion (e.g., total volume) of the second and fourth layers RL2 and RL4 in the anti-reflection layer RL (e.g., a total volume of the anti-reflection layer RL). For example, a proportion of the volume of the high hardness layer of the total volume of the anti-reflection layer RL may be relatively greater than a proportion of the volume of the low hardness layer of the total volume of the anti-reflection layer RL.

For example, in an embodiment a first thickness TH1 of the first layer RL1 may be about 72 nanometers (nm), a second thickness TH2 of the second layer RL2 may be about 139 nm, a third thickness TH3 of the third layer RL3 may be about 10 nm, a fourth thickness TH4 of the fourth layer RL4 may be about 133 nm, and a fifth thickness TH5 of the fifth layer RL5 may be about 81 nm. The area of the first to fifth layers TH1 to TH5 in a plan view may be substantially equal to each other. In this embodiment, in the anti-reflection layer RL, a proportion of the first, third and fifth layers RL1, RL3, and RL5 may be about 37%, and a proportion of the second and fourth layers RL2 and RL4 may be about 63%.

As the thicknesses of the second and fourth layers RL2 and RL4 having high hardness are relatively thick and the proportion (e.g., total volume) of the second and fourth layers RL2 and RL4 in the anti-reflection layer RL is relatively large, hardness of the anti-reflection layer RL may be increased. For example, a hardness of the window WN including the anti-reflection layer RL may be increased, and a strength of the window WN may be increased.

In addition, as the thickness of the second and fourth layers RL2 and RL4 having a high hardness is relatively thick and the proportion of the second and fourth layers RL2 and RL4 in the anti-reflection layer RL is relatively large, film stress of the anti-reflection layer RL may be increased. In a comparative embodiment in which a window coated with the anti-reflection layer RL on a glass product does not include the stress compensation layer GL2 (e.g., a glass product including only the base substrate GL1) is formed, bending (e.g., warpage) of the window may occur. For example, the window may be convexly bent in a direction toward the anti-reflection layer RL due to tensile stress of the anti-reflection layer RL. For example, an edge of the window may be bent toward the glass product.

Although FIG. 6 illustrates that the anti-reflection layer RL has a structure in which five layers are stacked, embodiments of the present disclosure are not necessarily limited thereto. In some embodiments, the anti-reflection layer RL may have various different structures in which two or more layers are stacked (e.g. in the third direction DR3).

Each of the glass product GL and the anti-reflection layer RL may cause bending of the window WN. The glass product GL (e.g., the stress compensation layer GL2) and the anti-reflection layer RL may cause bending of the window WN in opposite directions from each other.

In an embodiment, the anti-reflection layer RL is arranged on (e.g., disposed directly thereon in the third direction DR3) the stress compensation layer GL2 of the glass product GL in which ion exchange is active and ion diffusion is inhibited, thereby offsetting stress (e.g., an intrinsic stress) of the glass product GL and stress (e.g., an intrinsic stress) of the anti-reflection layer RL. For example, the stress of the anti-reflection layer RL may be compensated for by the stress of the glass product GL including the stress compensation layer GL2. For example, in some embodiments, the stress of the glass product GL that causes bending of the window WN in a first direction (e.g., in a direction opposite to the third direction DR3) may be substantially equal to the stress of the anti-reflection layer RL that causes bending of the window WN in an opposite second direction (e.g., in the third direction DR3) so that the forces offset each other and bending of the window WN is reduced or eliminated. Bending due to the stress imbalance between both surfaces of the glass product GL after chemical strengthening may be reduced or eliminated by the coating of the anti-reflection layer RL, and thus, occurrence of bending of the window WN may be effectively reduced.

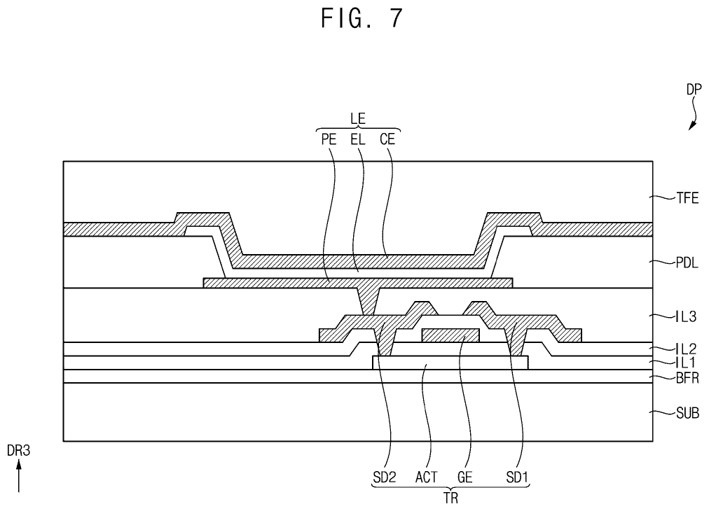

FIG. 7 is a cross-sectional view illustrating a display panel of the display device of FIG. 1. For example, FIG. 7 may be a cross-sectional view illustrating a portion of the display area DA.

Referring to FIGS. 2 and 7, in an embodiment the display panel DP may include a substrate SUB, a buffer layer BFR, a transistor TR, a first insulating layer IL1, a second insulating layer IL2, a third insulating layer IL3, a light emitting element LE, a pixel defining layer PDL, and an encapsulation layer TFE. In an embodiment, the transistor TR may include an active pattern ACT, a gate electrode GE, a first electrode SD1, and a second electrode SD2, and the light emitting element LE may include a pixel electrode PE, a light emitting layer EL, and a common electrode CE.

The buffer layer BFR may be arranged on the substrate SUB (e.g., disposed directly thereon in the third direction DR3). The buffer layer BFR may prevent metal atoms, impurities, or the like from diffusing into the transistor TR. In an embodiment, the buffer layer BFR may include an inorganic material such as silicon oxide (SiOₓ), silicon nitride (SiNₓ), silicon oxynitride (SiOₓN_{y}), or the like. These materials may be used alone or in combination with each other.

The active pattern ACT may be arranged on the buffer layer BFR (e.g., disposed directly thereon in the third direction DR3). The active pattern ACT may include a source area, a drain area, and a channel area between the source area and the drain area. In an embodiment, the active pattern ACT may include a silicon semiconductor material, an oxide semiconductor material, or the like. Examples of the silicon semiconductor material may include amorphous silicon, polycrystalline silicon, or the like. Examples of the oxide semiconductor material may include indium gallium zinc oxide (IGZO), indium tin zinc oxide (ITZO), or the like. These materials may be used alone or in combination with each other.

The first insulating layer IL1 may be arranged on (e.g., disposed directly thereon) the active pattern ACT, and may cover at least a portion of the active pattern ACT. In an embodiment, the first insulating layer IL1 may include an inorganic material such as silicon oxide, silicon nitride, silicon oxynitride, or the like. These materials may be used alone or in combination with each other.

The gate electrode GE may be arranged on the first insulating layer IL1 (e.g., disposed directly thereon in the third direction DR3). The gate electrode GE may overlap the channel area of the active pattern ACT in a plan view. In an embodiment, the gate electrode GE may include a metal, an alloy, a conductive metal oxide, a conductive metal nitride, a transparent conductive material, or the like. These materials may be used alone or in combination with each other.

The second insulating layer IL2 may be arranged on (e.g., disposed directly thereon) the gate electrode GE, and may cover the gate electrode GE. In an embodiment, the second insulating layer IL2 may include an inorganic material such as silicon oxide, silicon nitride, silicon oxynitride, or the like. These materials may be used alone or in combination with each other.

The first electrode SD1 and the second electrode SD2 may be arranged on the second insulating layer IL2 (e.g., disposed directly thereon in the third direction DR3). In an embodiment, the first electrode SD1 may be electrically connected to the source area of the active pattern ACT through a first contact hole penetrating a lower insulating layer (e.g., the first insulating layer IL1 and the second insulating layer IL2). The second electrode SD2 may be electrically connected to the drain area of the active pattern ACT through a second contact hole penetrating a lower insulating layer (e.g., the first insulating layer IL1 and the second insulating layer IL2). In an embodiment, the first electrode SD1 and the second electrode SD2 may include a metal, an alloy, a conductive metal oxide, a conductive metal nitride, a transparent conductive material, or the like. These materials may be used alone or in combination with each other.

Accordingly, the transistor TR including the active pattern ACT, the gate electrode GE, the first electrode SD1, and the second electrode SD2 may be arranged in the display area DA on the substrate SUB. The transistor TR may be included in the pixel circuit.

The third insulating layer IL3 may be arranged on (e.g., disposed directly thereon) the first electrode SD1 and the second electrode SD2, and may cover the first electrode SD1 and the second electrode SD2. In an embodiment, the third insulating layer IL3 may include an organic material such as a phenol resin, an acrylic resin, a polyimide resin, a polyamide resin, a siloxane resin, an epoxy resin, or the like. These materials may be used alone or in combination with each other.

The pixel electrode PE may be arranged on the third insulating layer IL3 (e.g., disposed directly thereon in the third direction DR3). The pixel electrode PE may be electrically connected to the transistor TR. For example, the pixel electrode PE may be electrically connected to the second electrode SD2 (or the first electrode SD1) through a contact hole penetrating a lower insulating layer (e.g., the third insulating layer IL3). In an embodiment, the pixel electrode PE may include a metal, an alloy, a conductive metal oxide, a conductive metal nitride, a transparent conductive material, or the like. These materials may be used alone or in combination with each other.

The pixel defining layer PDL may be arranged on (e.g., disposed directly thereon) the third insulating layer IL3 and the pixel electrode PE. In an embodiment, the pixel defining layer PDL may cover an edge (e.g., lateral edges) of the pixel electrode PE, and may define an opening exposing at least a portion of an upper surface of the pixel electrode PE. For example, in an embodiment the opening may expose a central portion of the upper surface of the pixel electrode PE. In an embodiment, the pixel defining layer PDL may include an organic material such as a polyimide resin, an epoxy resin, a siloxane resin, or the like. These materials may be used alone or in combination with each other.

The light emitting layer EL may be arranged on the pixel electrode PE (e.g., in the third direction DR3). The light emitting layer EL may be arranged on the upper surface of the pixel electrode PE exposed by the pixel defining layer PDL. The light emitting layer EL may include a material that emits light of a selected color. For example, in an embodiment the light emitting layer EL may include a material that emits red light, green light, or blue light, but embodiments of the present disclosure are not necessarily limited thereto.

The common electrode CE may be arranged on (e.g., disposed directly thereon) the pixel defining layer PDL and the light emitting layer EL. The common electrode CE may include a metal, an alloy, a conductive metal oxide, a conductive metal nitride, a transparent conductive material, or the like. These materials may be used alone or in combination with each other.

Accordingly, the light emitting element LE including the pixel electrode PE, the light emitting layer EL, and the common electrode CE may be arranged in the display area DA on the substrate SUB. The light emitting element LE may be electrically connected to the transistor TR. The light emitting element LE may generate light corresponding to a driving current provided from the transistor TR. The transistor TR and the light emitting element LE may correspond to a pixel (e.g., each of the pixels PX of FIG. 1).

The encapsulation layer TFE may be arranged on the common electrode CE (e.g., disposed directly thereon in the third direction DR3). The encapsulation layer TFE may protect the light emitting element LE from external moisture, oxygen, or the like. In an embodiment, the encapsulation layer TFE may include at least one inorganic layer and at least one organic layer. For example, in some embodiments the encapsulation layer TFE may include first and second inorganic layers with an organic layer disposed therebetween (e.g., in the third direction DR3).

The display device DD according to an embodiment of the present disclosure may include the window WN including the glass product GL manufactured by a float process to include the stress compensation layer GL2 (e.g., a tin surface) and the anti-reflection layer RL arranged on the stress compensation layer GL2. The stress compensation layer GL2 and the anti-reflection layer RL may cause bending of the window WN in opposite directions from each other, and the stress of the anti-reflection layer RL, which causes the window WN to be bent in one direction (e.g., the third direction DR3), may be compensated for by the stress of the glass product GL including the stress compensation layer GL2, which causes the window WN to be bent in a direction opposite to the one direction (e.g., a direction opposite to the third direction DR3). Accordingly, bending of the window WN may be minimized.

For example, in some embodiments, the magnitude that the glass product GL including the stress compensation layer GL2 causes bending of the window WN (e.g., in a direction opposite to the third direction DR3) may be substantially equal to the magnitude that the anti-reflection layer RL causes bending of the window WN (in the third direction DR3).

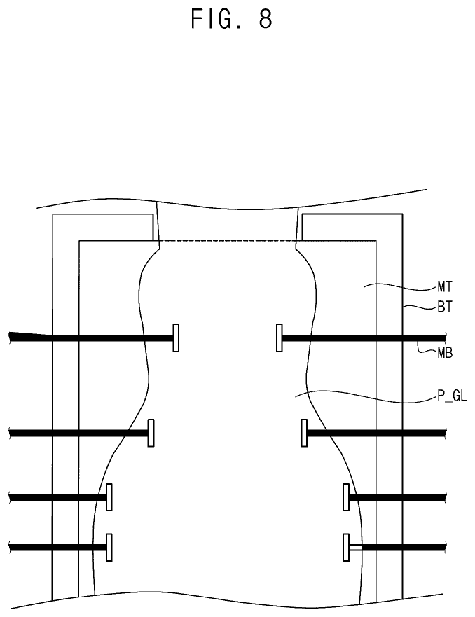

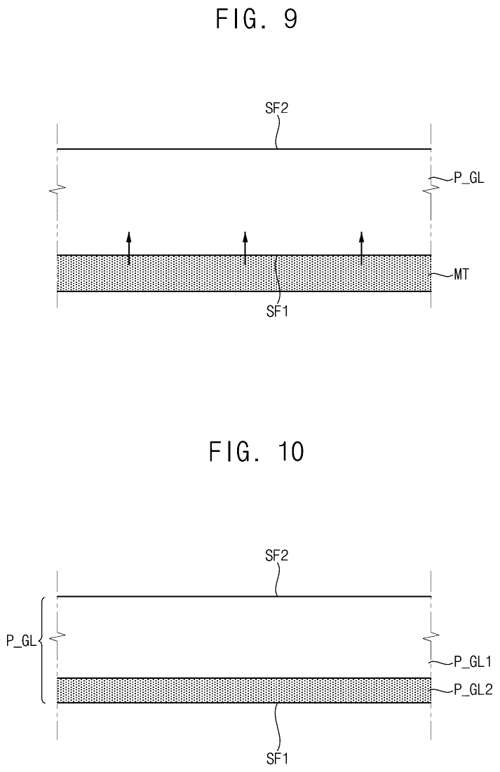

FIGS. 8, 9, 10, 11, 12, 13, and 14 are views illustrating a method of manufacturing a window according to an embodiment of the present disclosure. The method of manufacturing a window described with reference to FIGS. 8, 9, 10, 11, 12, 13, and 14 may be a method of manufacturing the window WN included in the display device DD described with reference to FIGS. 1, 2, 3, 4, 5, 6, and 7. Hereinafter, redundant descriptions will be omitted or simplified for economy of explanation.

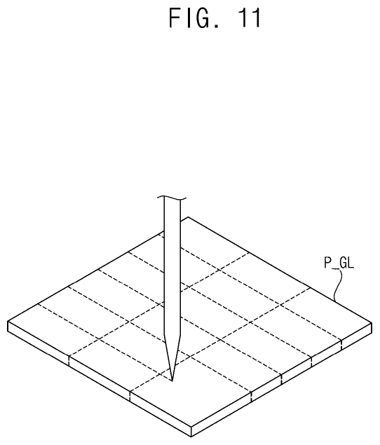

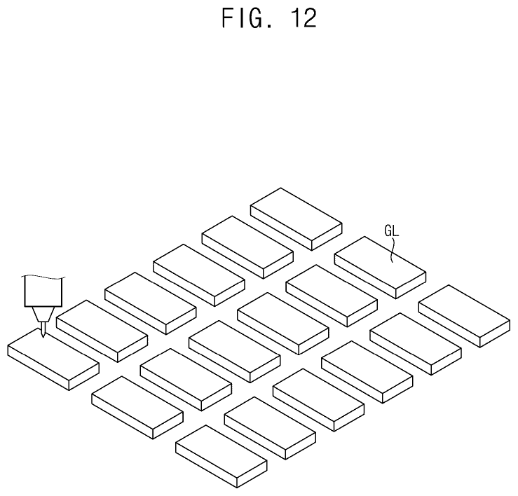

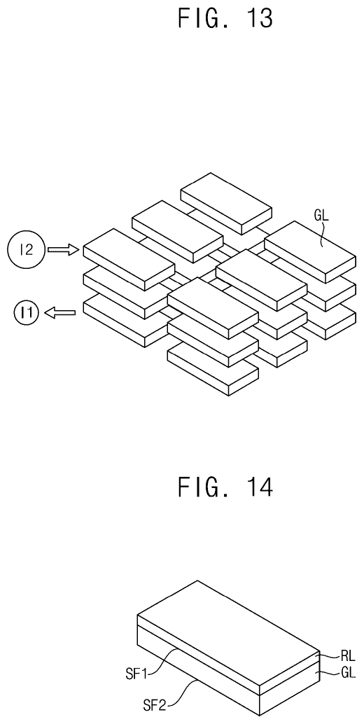

FIGS. 8, 9, and 10 may be views schematically illustrating a molding process of a preliminary glass product. FIG. 11 may be a view schematically illustrating a cutting process of the preliminary glass product. FIG. 12 may be a view schematically illustrating a processing process of a glass product. FIG. 13 may be a view schematically illustrating a strengthening process of the glass product. FIG. 14 may be view schematically illustrating a coating process of the glass product.

Referring to FIGS. 8, 9, and 10, in an embodiment a molding process of a preliminary glass product P_GL may be performed to mold the preliminary glass product P_GL. In an embodiment, the molding process may be performed by a float process. In the molding process, a glass composition may be molded into a plate glass shape by the float process, so that the preliminary glass product P_GL may be manufactured.

In an embodiment, the glass composition may include silicon oxide (SiOₓ). For example, the glass composition may include silicon dioxide (SiO₂), and may further include materials such as aluminum oxide (Al₂O₃), lithium oxide (LiO₂), sodium oxide (Na₂O), or the like. However, embodiments of the present disclosure are not necessarily limited thereto, and the glass composition may further include other materials as necessary.

The glass composition may be melted by being heated by a heating source in a molten chamber. In an embodiment, the heating source may heat to a temperature higher than a melting point of the glass composition. A process of manufacturing the glass composition in the molten chamber is widely known in the art, and thus a detailed description thereof will be omitted for economy of explanation.

The glass composition may be molded in a bath BT to be manufactured into the preliminary glass product P_GL. The glass composition introduced into the molten chamber may be introduced into the bath BT in an atypical state. Molten tin MT may be accommodated in (e.g., disposed therein) the bath BT.

For example, the molten tin MT melted at a temperature in a range of about 700° C. to about 1200° C. may be accommodated inside the bath BT. The introduced glass composition in a molten state may be located on the molten tin MT due to a difference in density with the molten tin MT. For example, the preliminary glass product P_GL may be manufactured in a floating state on the molten tin MT. The glass composition introduced into the bath BT in a fluid state may be pulled left and right on a horizontal plane of the bath BT by a plurality of molding bars MB to be molded into the preliminary glass product P_GL of a desired shape.

In the molding process, since the molten tin MT is present at a lower portion of the preliminary glass product P_GL, a portion of tin ions may penetrate into the preliminary glass product P_GL directly contacting the molten tin. Accordingly, the preliminary glass product P_GL may include a preliminary stress compensation layer P_GL2 in which the tin ions have penetrated and a preliminary base substrate P_GL1 arranged on (e.g., disposed directly thereon) the preliminary stress compensation layer P_GL2.

The preliminary stress compensation layer P_GL2 may be formed on one surface of the preliminary glass product P_GL directly contacting the molten tin MT in the bath BT, and the one surface may be the first surface SF1. For example, the tin ions may penetrate through the first surface SF1. The preliminary base substrate P_GL1 may be formed on the other surface of the preliminary glass product P_GL, which faces the one surface, and the other surface may be the second surface SF2. The tin ions of the preliminary stress compensation layer P_GL2 may cause a difference in ion exchange and ion diffusion rates in a subsequent chemical strengthening process, and thus, a difference in compression stress may occur in a glass product manufactured through chemical strengthening as described above, thereby causing bending of the glass product.

Referring to FIG. 11, a cutting process of the preliminary glass product P_GL may be performed to cut the preliminary glass product P_GL. For example, the cutting process of the preliminary glass product P_GL may be performed after the molding process of the glass composition.

The preliminary glass product P_GL may have a different size from that of the glass product GL of FIG. 3. For example, in an embodiment the cutting process of the preliminary glass product P_GL may be performed in a large-area substrate state as the preliminary glass product P_GL including a plurality of glass products GL, and the glass products GL may be manufactured by cutting the preliminary glass product P_GL into a plurality of pieces. For example, in an embodiment the cutting process of the preliminary glass product P_GL may be performed using a cutting knife, a cutting wheel, a laser, or the like.

Referring to FIG. 12, a processing process of the glass product GL may be performed to process the glass product GL. For example, the processing process of the glass product GL may be performed after the cutting process of the preliminary glass product P_GL.

In an embodiment, the glass product GL may be processed into a computer numerical control (CNC). The glass product GL may be three-dimensionally processed using CNC processing equipment. For example, in an embodiment the glass product GL may be processed such that a corner of one surface of the glass product GL is rounded. However, embodiments of the present disclosure are not necessarily limited thereto, and the glass product GL may be processed into various shapes.

Referring to FIG. 13, a strengthening process of the glass product GL may be performed to strengthen the glass product GL. For example, the strengthening process of the glass product GL may be performed after the processing process of the glass product GL.

In an embodiment, the strengthening process may be performed by a chemical strengthening process and/or a thermal strengthening process. Hereinafter, an embodiment in which a chemical strengthening process is performed as the strengthening process of the glass product GL will be described.

In an embodiment, the chemical strengthening process may be performed through ion exchange. The ion exchange may be a process of exchanging (or replacing) ions in the glass product GL with other ions, and the ion exchange process may be performed one or more times.

Through the ion exchange, the first ion I1 on a surface and near the surface of the glass product GL may be exchanged by the second ion I2 having the same valence or oxidation state and having a larger ion radius. For example, in an embodiment in which the glass product GL includes the first ion I1 such as Li⁺, Na⁺, K⁺, Rb⁺, or the like, the first ion I1 on the surface of the glass product GL may be exchanged with the second ion I2 having a larger ion radius than the first ion I1 such as Na⁺, K⁺, Rb⁺, Cs⁺, or the like.

In an embodiment, the chemical strengthening process may be a single-salt or mixed-salt wet chemical strengthening process by an immersion method. The chemical strengthening process may be performed by immersing the glass product GL in a molten salt (e.g., the molten salt MS of FIG. 8) accommodated in a bath (e.g., the bath BT of FIG. 8) and including the second ion I2. For example, the chemical strengthening process may be performed at a temperature of the molten salt in a range of 300° C. to 500° C. for 1 hour to 30 hours using the molten salt such as potassium nitrate (KNO₃) or sodium nitrate (NaNO₃). However, embodiments of the present disclosure are not necessarily limited thereto.

Referring to FIGS. 13 and 14, a coating process of the glass product GL may be performed to coat the glass product GL. For example, the coating process of the glass product GL may be performed after the strengthening process of the glass product GL.

The second ion I2 may be densely distributed near the first surface SF1 of the glass product GL. A greater amount of the second ion I2 may be distributed in a narrower thickness area in the first compression area SA1 of FIG. 4 than in the second compression area SA2 of FIG. 4. For example, a density of the second ion I2 may be greater near the first surface SF1 than near the second surface SF2.

When a difference in compression stress occurs on both surfaces facing each other of a glass, an edge of the glass may be bent towards a surface with a greater compression stress. In an embodiment, the compression stress of the first surface SF1 of the glass product GL may be greater than the compressive stress of the second surface SF2 of the glass product GL due to the stress compensation layer GL2 in which the second ions I2 are distributed at a high density, and thus, the edge of the glass product GL may be bent towards the first surface SF1.

In an embodiment, the anti-reflection layer RL may be coated (e.g., formed) on the first surface SF1 of the glass product GL. The thickness and proportion of the high hardness layer (e.g., the second and fourth layers RL2 and RL4 of FIG. 6) in the anti-reflection layer RL may be relatively large, and accordingly, the film stress of the anti-reflection layer RL may be increased.

When the anti-reflection layer RL having an increased thickness and proportion of the high hardness layer is coated on a glass, an edge of the glass may be bent towards a surface on which the anti-reflection layer RL is not coated (e.g., a surface with low tensile stress). In an embodiment, the anti-reflection layer RL may be coated on the first surface SF1 of the glass product GL, and accordingly, an edge of the glass product GL coated with the anti-reflection layer RL may be bent towards the second surface SF2.

Referring further to FIG. 3, in an embodiment, the window WN may have a factor of bending in one direction (e.g., a direction opposite to the third direction DR3) due to the stress compensation layer GL2 of the glass product GL, and may have a factor of bending in a direction opposite to the one direction (e.g., the third direction DR3) due to the anti-reflection layer RL. Accordingly, stress (or bending) of the window WN may be compensated to reduce a degree of bending of the window WN. For example, in an embodiment, the bending of the stress compensation layer GL2 in the one direction may have a substantially equal magnitude as the bending of the anti-reflection layer RL in the opposite direction to the one direction.

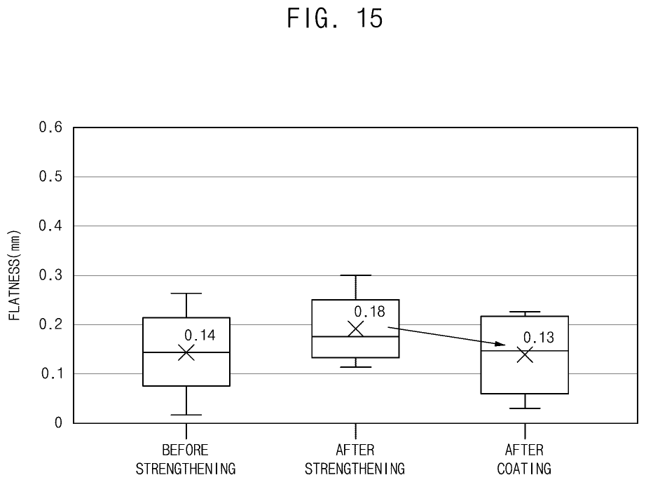

FIG. 15 is a graph comparing flatness of windows of comparative example and an embodiment.

For example, flatness may be quantified through a difference between maximum and minimum values by measuring heights of feature points (e.g., vertices of one surface of glass, center of one surface of glass, or the like) from a reference plane in a flat-shaped glass. Here, a smaller flatness value indicates increased flatness.

Referring to FIGS. 3 and 15, “before strengthening” is a first comparative example, a case before strengthening the glass product GL, “after strengthening” is a second comparative example, a case after strengthening the glass product GL, and both cases are examples of a window in which the anti-reflection layer RL is not coated on the first surface SF1 of the glass product GL (e.g., on the stress compensation layer GL2). “After coating” is an embodiment of the present disclosure, and is an example of the window WN in which the anti-reflection layer RL is coated on the first surface SF1 of the glass product GL after strengthening the glass product GL.

FIG. 15 shows an average flatness of the examples (e.g., the first comparative example, the second comparative example, and an example according to an embodiment of the present disclosure). The average flatness of the first comparative example corresponds to 0.14 mm, the average flatness of second comparative example corresponds to 0.18 mm, and the average flatness of an example according to an embodiment of the present disclosure corresponds to 0.13 mm. Accordingly, when compared with the comparative examples, it is confirmed that the flatness is increased in the example according to an embodiment of the present disclosure.

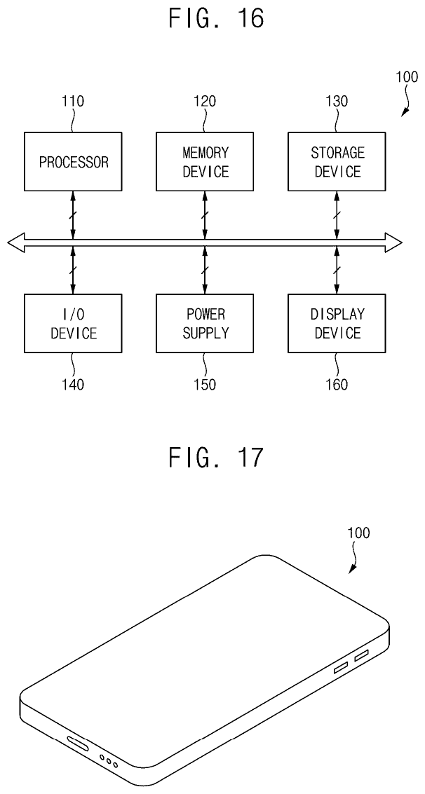

FIG. 16 is a block diagram illustrating an electronic device according to an embodiment of the present disclosure. FIG. 17 is a diagram illustrating an example in which the electronic device of FIG. 16 is implemented as a smartphone.

Referring to FIGS. 16 and 17, an electronic device 100 may include a processor 110, a memory device 120, a storage device 130, an input/output (I/O) device 140, a power supply 150, and a display device 160. The display device 160 may be the above-described display device DD. The electronic device 100 may further include a plurality of ports for communicating with a video card, a sound card, a memory card, a universal serial bus (USB) device, other systems, or the like.

In an embodiment, as illustrated in FIG. 17, the electronic device 100 may be implemented as a smartphone. However, this is merely an example, and the electronic device 100 is not necessarily limited thereto. For example, in some embodiments the electronic device 100 may be implemented as a cellular phone, a video phone, a television, a smart pad, a smart watch, a tablet computer, a vehicle display, a computer monitor, a laptop/notebook computer, a head mounted display (HMD), or the like. The electronic device 100 may be implemented in various other small-sized, medium-sized or large-sized electronic devices.

The processor 110 may perform various computing functions. The processor may control the display device 160. The processor 110 may be a microprocessor, a central processing unit (CPU), an application processor (AP), or the like. The processor 110 may be coupled to other components through an address bus, a control bus, a data bus, or the like. In an embodiment, the processor 110 may be coupled to an extended bus such as a peripheral component interconnection (PCI) bus.

The memory device 120 may store data for operations of the electronic device 100. For example, the memory device 120 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, or the like and/or at least one volatile memory device such as a dynamic random access memory (DRAM) device, a static random access memory (SRAM) device, a mobile DRAM device, or the like.

The storage device 130 may include a solid-state drive (SSD) device, a hard disk drive (HDD) device, a CD-ROM device, or the like. The I/O device 140 may include an input device such as a keyboard, a keypad, a mouse device, a touch-pad, a touch-screen, or the like, and an output device such as a printer, a speaker, or the like.

The power supply 150 may provide power for operations of the electronic device 100. The display device 160 may be connected to other components through buses or other communication links. In an embodiment, the display device 160 may be included in the I/O device 140.

Embodiments of he present disclosure may be applied to various display devices and electronic devices. For example, embodiments of the present disclosure are applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few non-limiting embodiments have been described, those skilled in the art will readily appreciate that many modifications are possible in the described embodiments without materially departing from the novel teachings and advantages of the present disclosure. Accordingly, all such modifications are intended to be included within the scope of the present disclosure. Therefore, it is to be understood that the foregoing is illustrative of various embodiments and is not to be construed as limited to the specific embodiments disclosed, and that modifications to the described embodiments, as well as other embodiments, are intended to be included within the scope of the present disclosure.

What is claimed is:

1. A window comprising:
a glass product including:
a first surface;
a second surface facing the first surface in a thickness direction of the glass product, the second surface having a compression stress that is less than a compression stress of the first surface;
a base substrate defining the second surface; and
a stress compensation layer arranged on the base substrate, the stress compensation layer defining the first surface, and including a material different from a material of the base substrate; and
an anti-reflection layer arranged on the first surface of the glass product.

2. The window of claim 1, wherein:
the glass product has a stress that bends the window in a first direction; and
the anti-reflection layer has a stress that bends the window in a second direction opposite to the first direction.

3. The window of claim 2, wherein the stress of the glass product is substantially equal to the stress of the anti-reflection layer.

4. The window of claim 1, wherein the stress compensation layer includes tin ions.

5. The window of claim 1, wherein the anti-reflection layer includes:
a first layer; and
a second layer arranged on the first layer, the second layer having a hardness greater than a hardness of the first layer.

6. The window of claim 5, wherein a thickness of the first layer is less than a thickness of the second layer.

7. The window of claim 5, wherein a proportion of a volume of the first layer in a total volume of the anti-reflection layer is less than a proportion of a volume of the second layer in the total volume of the anti-reflection layer.

8. The window of claim 5, wherein the first layer and the second layer are alternately arranged along a thickness direction of the anti-reflection layer.

9. The window of claim 1, wherein:
the glass product includes:
a first compression area extending from the first surface to a first depth; and
a second compression area extending from the second surface to a second depth, and
the first depth is less than the second depth.

10. The window of claim 1, wherein the glass product is manufactured by a float process.

11. A method of manufacturing a window, the method comprising:
forming a glass product, the glass product including:
a first surface;
a second surface facing the first surface in a thickness direction of the glass product, the second surface having a compression stress that is less than a compression stress of the first surface;
a base substrate defining the second surface; and
a stress compensation layer arranged on the base substrate, the stress compensation layer defining the first surface, and including a material different from a material of the base substrate; and
forming an anti-reflection layer on the first surface of the glass product.

12. The method of claim 11, wherein:
the glass product has a stress that bends the window in a first direction, and
in the forming of the glass product, the glass product is bent in the first direction by the stress of the glass product.

13. The method of claim 12, wherein:
the anti-reflection layer has a stress that bends the window in a second direction opposite to the first direction; and
in the forming of the anti-reflection layer, the glass product and the anti-reflection layer are bent in the second direction opposite to the first direction by the stress of the anti-reflection layer.

14. The method of claim 13, wherein the stress of the glass product is substantially equal to the stress of the anti-reflection layer.

15. The method of claim 11, wherein:
the glass product is manufactured by a float process, and
the stress compensation layer includes tin ions.

16. The method of claim 11, wherein the anti-reflection layer includes:
a first layer; and
a second layer arranged on the first layer and having a hardness greater than a hardness of the first layer.

17. The method of claim 16, wherein a thickness of the first layer is less than a thickness of the second layer.

18. The method of claim 16, wherein a proportion of a volume of the first layer in a total volume of the anti-reflection layer is less than a proportion of a volume of the second layer in the total volume of the anti-reflection layer.

19. The method of claim 16, wherein the first layer and the second layer are alternately arranged along a thickness direction of the anti-reflection layer.

20. An electronic device comprising:
a display device including:
a display panel including a plurality of pixels arranged in a display area; and
a window arranged on the display panel; and
a processor that controls the display device,
wherein the window includes:
a glass product including:
a first surface;
a second surface facing the first surface in a thickness direction of the glass product, the second surface having a compression stress that is less than a compression stress of the first surface;
a base substrate defining the second surface; and
a stress compensation layer arranged on the base substrate, the stress compensation layer defining the first surface, and including a material different from a material of the base substrate; and
an anti-reflection layer arranged on the first surface of the glass product.
